(19) United States
(12) Patent Application Publication
(10) Pub. No.: US 2004/0130036 A1
(43) Pub. Date: Jul. 8, 2004

(54) Mult-chip module

(75) Inventors: Masanori Owaki, Kodaira (JP); Toshikazu Ishikawa, Kodaira (JP); Takahiro Naito, Kodaira (JP); Makoto Suzuki, Higashimurayama (JP); Takafumi Kikuchi, Higashiyamato (JP); Takashi Ozawa, Jouetsu (JP)

Correspondence Address: MILES & STOCKBRIDGE PC, 1751 PINNACLE DRIVE, SUITE 500, MCLEAN, VA, 22102-3833, US

(73) Assignees: Renesas Technology Corp.; Shinko Electric Industries Co., Ltd.

(21) Appl. No.: 10/714,983

(22) Filed: Nov. 18, 2003

(30) Foreign Application Priority Data
Nov. 28, 2002 (JP) 2002-344782

(51) Int. Cl. H01L 23/48

(52) U.S. Cl. 257/777; 257/686

(57) ABSTRACT

A compact multi-chip module having a high performance is provided. A plurality of first semiconductor chips for exchanging signals are surface-mounted on a surface of a mounting board. A second semiconductor chip with most of bonding pads thereof arranged along one side thereof is mounted back-to-back with at least one of the first semiconductor chips on the mounting board. The bonding pads of the second semiconductor chip and corresponding electrodes formed on the mounting board are connected by wire bonding. The first and second semiconductor chips and bonding wires on the mounting board are encapsulated with a sealing material.

### BACKGROUND OF THE INVENTION

The present invention relates to a multi-chip module (MCM), and in particular to a technique effectively applicable to the multi-chip module in which a plurality of semiconductor chips having several different functions are integrally mounted on a single board thereby to form the plurality of the semiconductor chips into a substantially single semiconductor integrated circuit device.

In what is called the multi-chip module technique, a plurality of semiconductor chips are mounted on a board having a plurality of internal wirings and a plurality of external terminals, and the plurality of the semiconductor chips are integrated with the mounting board as a circuit device. JP-A-2001-320014 and JP-A-2000-299431 disclose examples of a two-chip stack structure in which an upper chip is larger than a lower chip. JP-A-11-219989, on the other hand, discloses an example of a two-chip stack structure in which a flash memory and a SRAM are combined with each other.

### SUMMARY OF THE INVENTION

The semiconductor technique is making progress in such a direction that a plurality of semiconductor chips such as a microcomputer chip, a DRAM chip and a flash memory chip making up an electronic system are configured as a single package as a semiconductor device. Specifically, in the case where a plurality of semiconductor devices each comprising a single semiconductor chip, not a plurality of semiconductor chips, are packaged by the usual packaging technique such as QFP (Quad Flat Package), CSP (Chip Size Package or Chip Scale Package) or BGA (Ball Grid Array) and mounted on a mounting board such as a printed board, the distance and the wiring distance between the semiconductor chips cannot be easily reduced, with the result that a large signal delay due to the wiring hampers both the increase in device operation speed and the device size reduction.

According to the multi-chip module technique, in contrast, a plurality of very small semiconductor chips in the form of what are called bare chips are fabricated into a semiconductor device in a single package. Therefore, the wiring distance between the chips can be reduced and the characteristics of the semiconductor device can be improved. Also, since a plurality of semiconductor chips are formed into a single package, the semiconductor device can be reduced in size with a reduced packaging area.

The semiconductor chips selected for a multi-chip module preferably include closely related ones such as a microcomputer chip, a DRAM or a flash memory chip coupled with the microcomputer chip. The features of the multi-chip module can be sufficiently exhibited by selecting a combination of a plurality of closely related semiconductor chips as described above. JP-A-2001-320014, JP-A-2000-299431 and JP-A-11-219989, however, take into consideration neither the improvement of the overall functions constituting a feature of the multi-chip module nor the device size reduction, but simply employ a stack structure of individual chips.

The object of this invention is to provide a multi-chip module reduced in size while at the same time improving the performance. The above and other objects, features and advantages are made apparent by the detailed description taken in conjunction with the accompanying drawings.

Typical aspects of the invention disclosed herein are briefly described below. A plurality of first semiconductor chips adapted to exchange signals with each other are surface-mounted on the surface of a mounting board, and a second semiconductor chip with a greater part of bonding pads arranged along one side thereof is mounted back-to-back with at least one of the first semiconductor chips, and the bonding pads and corresponding electrodes formed on the mounting board are connected to each other by wire bonding. The first and second semiconductor chips and the bonding wires on the mounting board are encapsulated with a sealing material.

### BRIEF DESCRIPTION OF THE DRAWINGS

FIG. 1 is a top plan view showing a multi-chip module according to an embodiment of the invention.

FIG. 2 shows a chip layout on the surface of the mounting board of the multi-chip module in FIG. 1.

FIGS. 3A and 3B are sectional views schematically showing the multi-chip module of FIG. 1.

FIG. 4 is a schematic diagram for explaining the assembly steps of a multi-chip module according to the invention.

FIG. 5 is a block diagram showing a multi-chip module according to an embodiment of the invention.

FIG. 6 is a diagram showing a pattern of a mounting board for a multi-chip module according to an embodiment of the invention.

FIG. 7 shows a layout of the bonding pads of a flash memory according to an embodiment of the invention.

FIG. 8 is a diagram showing the general configuration of a multi-chip module according to an embodiment of the invention.

FIG. 9 is a schematic diagram showing an example of a general layout of a multi-chip module studied prior to this invention.

FIG. 10 is a sectional view of the essential parts showing a modification of a multi-chip module according to the invention.

FIG. 11 is a sectional view of the essential parts showing the method of fabricating the multi-chip module of FIG. 10.

FIG. 12 is a sectional view of the essential parts showing the method of fabricating the multi-chip module of FIG. 10.

FIG. 13 is a sectional view of the essential parts showing the method of fabricating the multi-chip module of FIG. 10.

### DETAILED DESCRIPTION OF THE INVENTION

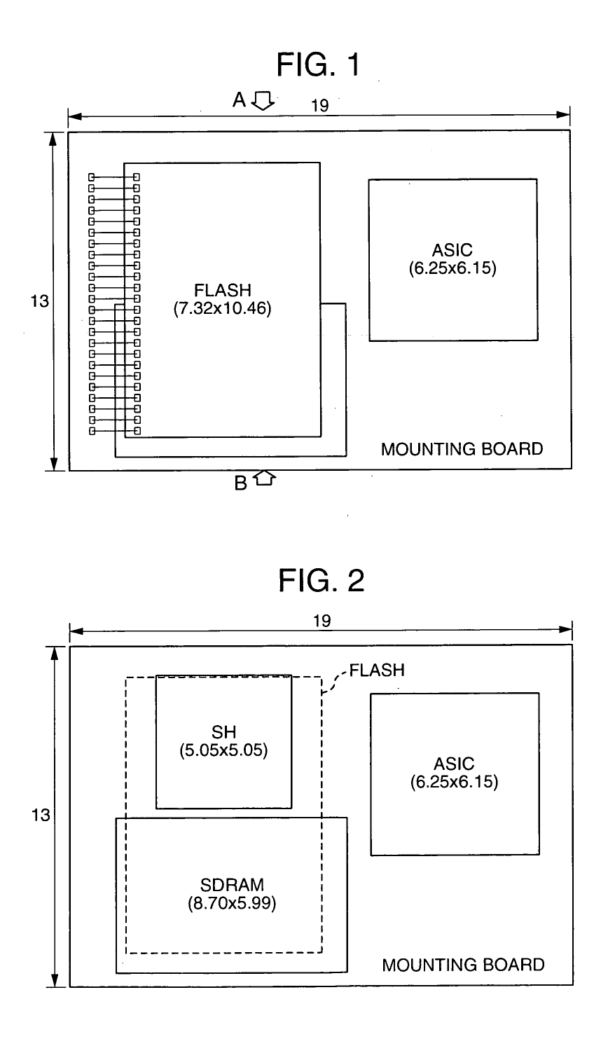

FIG. 1 shows a top plan view of a multi-chip module according to an embodiment of the invention. A flash EEPROM (flash electrically erasable and programmable read only memory, hereinafter referred to simply as “a flash memory”) FLASH and a digital signal apparatus ASIC are mounted on the package board. Under the flash memory FLASH described above, a microcomputer SH and a synchronous dynamic random access memory SDRAM are mounted.

Specifically, the surface of the mounting board has mounted thereon by surface mounting as shown in FIG. 2, the microcomputer SH, the synchronous dynamic random access memory SDRAM and the digital signal device ASIC. The flash memory FLASH, as indicated by dotted line in FIG. 2, is mounted back-to-back (with the backs of the chips opposed to each other) over the two semiconductor chips SH and SDRAM.

The semiconductor chips SH, SDRAM and ASIC shown in FIG. 2 are mounted on one main surface of the mounting board in such a manner that the circuit formed surfaces of the semiconductor chips are in opposed relation to each other. A plurality of external terminals of the multi-chip module are arranged on the other main surface of the mounting board. This configuration makes possible a compact multi-chip module regardless of the area occupied by the plurality of the semiconductor chips and the area required for arranging the plurality of the external terminals.

The semiconductor chips SH, SDRAM and ASIC are configured of what is called bare chips, and have a plurality of bump electrodes adapted to be mounted by imposition on the mounting board. Each semiconductor chip is configured by a technique called the area array pad in which a wiring making possible the rearrangement of pad electrodes (bonding pads) through an insulating film of polyimide resin or the like is formed on the circuit formed surface of the semiconductor chip complete with the devices and the wiring, and the pad electrodes (bump connecting land electrodes) are formed on the wiring.

With the area array pad technique described above, the pad electrodes, which are arranged at comparatively small pitches such as several tens of μm or 100 μm as external terminals of the semiconductor chips SH, SDRAM and ASIC have a diameter of 0.1 mm to 0.2 mm, are converted into an arrangement of bump electrodes having a comparatively large pitch of 400 μm to 600 μm. The area array pad technique is effectively used for imposition of the semiconductor chips such as SDRAM with the input/output circuit and the pad electrodes thereof suitably arranged at the center of the semiconductor chip.

The mounting board has an insulating substrate of glass epoxy or glass, a comparatively fine internal wiring configured of a multilayer wiring structure formed on the insulating substrate, a plurality of lands to be electrically connected to the bump electrodes of the semiconductor chips, and a plurality of external terminals. The mounting board forms, on the main surface thereof to be formed with the semiconductor chips, electrodes for connecting by wire the bonding pads arranged on the flash memory FLASH, as well as the lands described above.

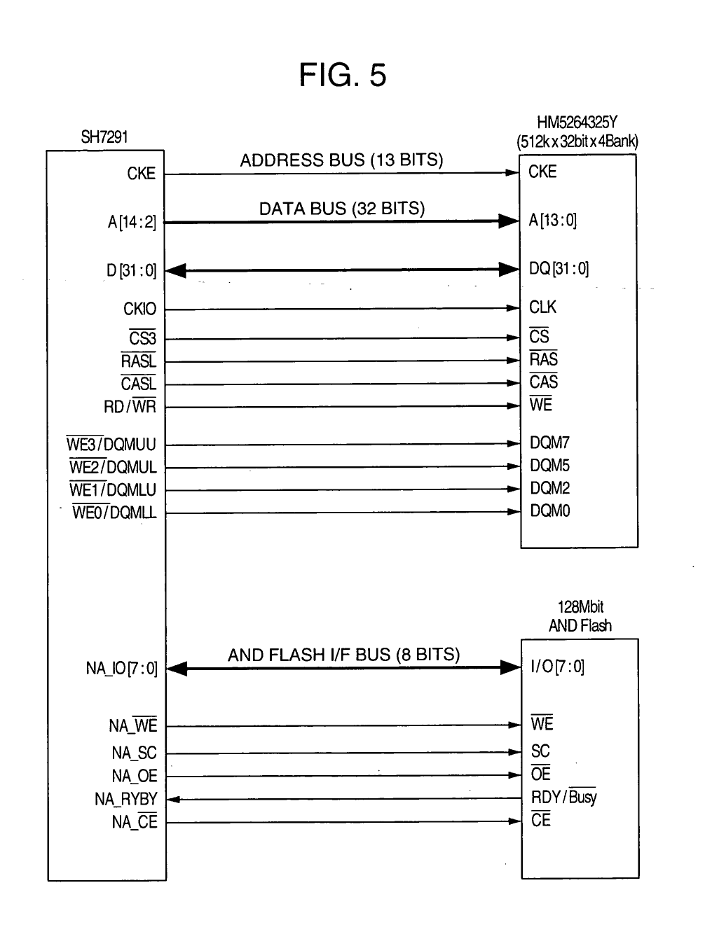

The flash memory according to this embodiment is of what is called AND type and has no independent address terminal. Address signals are serially input by time division using a data terminal. Specifically, in the flash memory according to this embodiment, as shown in FIG. 5, a command for designating an operating mode, an address and data are fetched through the data terminal I/O (7:0). The signal input through an input/output buffer is transmitted to the command decoder and the address counter through an internal signal line. For this purpose, bonding pads each indicated by a square are arranged along one side (the long side in this embodiment) of the semiconductor chip, and connected to corresponding electrodes on the mounting board by bonding wires.

FIGS. 1 and 2 illustratively show the size (lateral side by longitudinal side in mm) of the mounting board and the semiconductor chips SH, SDRAM, ASIC and FLASH. The mounting board has the size of 19 by 13, SH a size of 5.05 by 5.05, SDRAM a size of 8.70 by 5.99, ASIC a size of 6.25 by 6.15, and FLASH a size of 7.32 by 10.46. For the flash memory FLASH which is arranged vertically long, however, the size is expressed as horizontal length by vertical length.

In order to mount the four semiconductor chips efficiently on the mounting board, the rectangular chip SDRAM is placed with the long side thereof laterally, and the square-shaped chip SH is arranged vertically as illustrated in FIG. 2 thereby to match the length of the long side of the rectangular chip FLASH. In this way, the chip FLASH is arranged back-to-back with the chips SDRAM and SH to form a stack structure. Specifically, as viewed from the mounting board, the chip FLASH can be wholly mounted in the area of the mounting surface occupied by the chips SH and SDRAM. Thus, the four semiconductor chips including the chip FLASH can be mounted on the mounting board which otherwise could accommodate only three semiconductor chips including the chip ASIC.

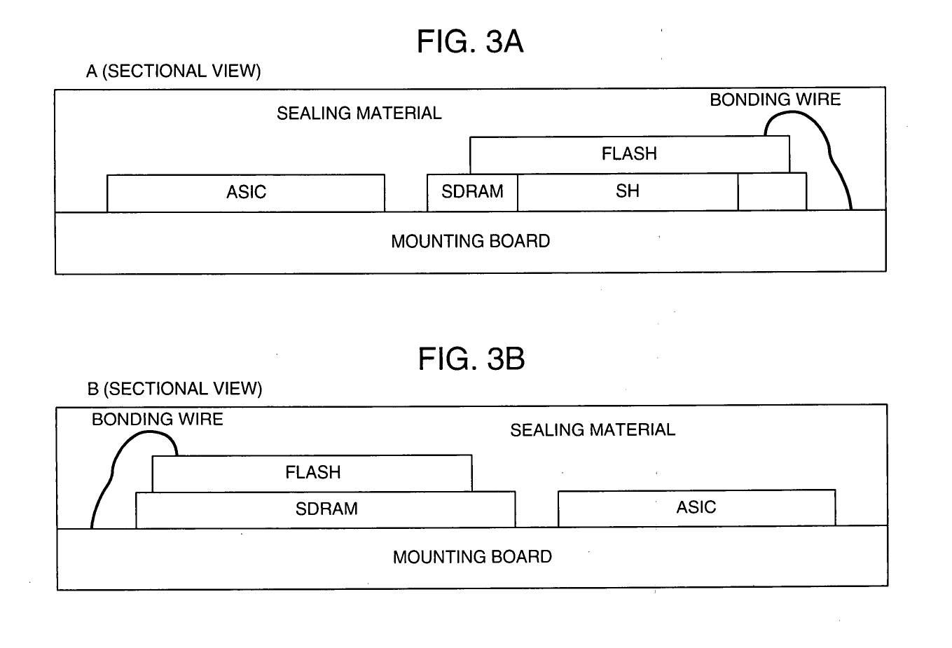

FIGS. 3A and 3B are sectional views schematically showing a multi-chip module according to the invention. FIG. 3A is a sectional view taken along arrow A in FIG. 1, and FIG. 3B is a sectional view taken along arrow B in FIG. 1. Thus, the views of FIGS. 3A and 3B are laterally reversed with each other. As described above, the semiconductor chips SH, SDRAM and ASIC are surface-mounted on the main surface of the mounting board, while the flash memory FLASH is mounted through a thermosetting adhesive or the like back-to-back with the semiconductor chips SH and SDRAM. Electrodes of the semiconductor chips are connected to corresponding electrodes of the mounting board by bonding wires (connector wires). The main surface of the mounting board on which the semiconductor chips SH, SDRAM, ASIC and FLASH are mounted is encapsulated with a sealing material, containing the bonding wire.

In FIGS. 3A and 3B, the external terminals of the multi-chip module, though not shown, are configured of bump electrodes adapted to be electrically connected to the internal wiring through the holes formed in the mounting board, and arranged on the other main surface (reverse side) of the mounting board. The bump electrodes of the semiconductor chips SH, SDRAM and ASIC may be called micro-bumps and comparatively small in size and pitch, while the bump electrodes providing the external terminals of the mounting board are comparatively large in size and pitch.

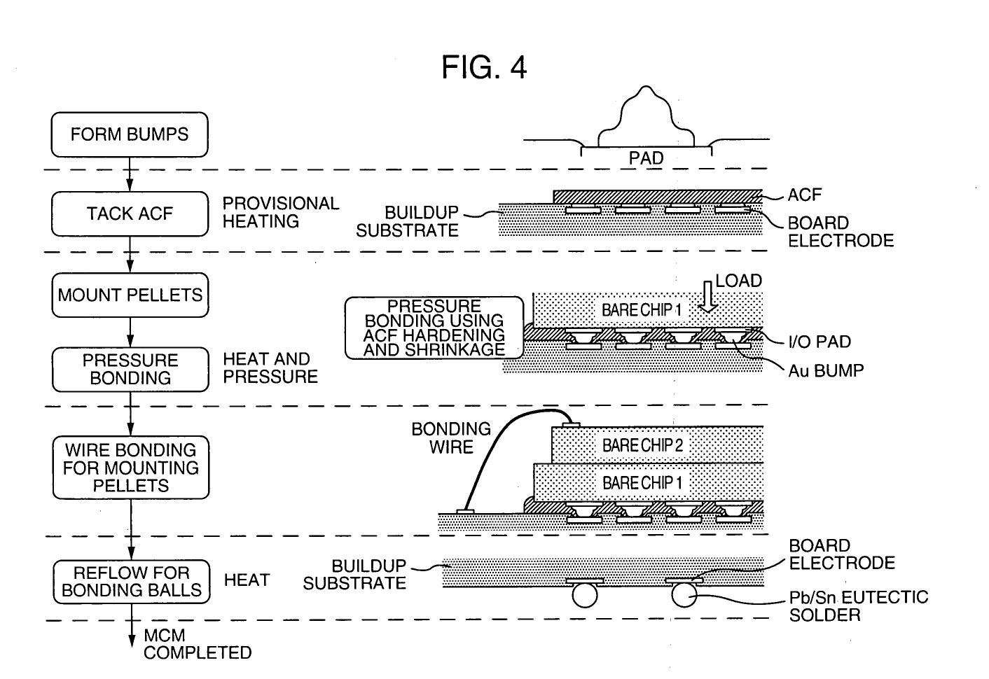

FIG. 4 is a schematic diagram for explaining the steps of assembling a multi-chip module according to the invention. The assembly steps and the corresponding thermal hysteresis and the general vertical structure are shown in FIG. 4. An Au bump is formed on the pad of a bare chip 1. An anisotropic conductive film ACF is tacked on the MCM substrate electrode, and a bare chip with the Au bump formed on the pad is mounted on the MCM substrate for thermo-compression bonding. A bare chip 2 is bonded by a thermosetting adhesive back-to-back with the bare chip 1, and connected to a corresponding electrode of the MCM substrate by wire bonding. In this way, though not shown, the assembly is encapsulated with resin. In the last step, a MCM is completed by formation of solder balls as external terminals, by reflow treatment.

FIG. 5 is a block diagram showing a multi-chip module according to an embodiment of the invention. In FIG. 5, the electrical connection of the microcomputer SH, the memory SDRAM and the flash memory FLASH in FIG. 1 is shown illustratively together with the signal terminal names.

In order to reduce the size of a multi-chip module with an improved performance while utilizing the features thereof derived from the combination of the microcomputer SH, the memory SDRAM (and the digital signal device ASIC) and the flash memory FLASH as shown in FIG. 1, the microcomputer SH and the memory SDRAM (and the digital signal device ASIC) exchanging signals with each other are interconnected by address buses (13 bits), data buses (32 bits) and control buses formed on the mounting board.

Thirteen (13) address buses, for example, correspond to the address terminals A0 to A12 of the SDRAM, and 32 data buses correspond to the data terminals DQ0 to DQ31 of SDRAM. The microcomputer SH has address buses connected to the address terminals A2 to A14, and the data buses connected to the terminals D0 to D31.

The microcomputer SH has the control output terminals CKIO, CKE, CS3B, RASLB, CASLB, RD/WRB, WE3B/DQMUU, WE2B/DQMUL WE1B/DQMLU and WEOB/DQMLL corresponding to the memory SDRAM, which are connected to CLK, CKE, CSB, RASB, CASB, WEB and DQM7, DQM5, DQM2, DQM0. The terminal names with B attached thereto correspond to the logic signals for raising the low active level with an over bar to the active level in the drawings. The terminals WE3B/DQMUU, WE2B/DQMUL, WE1B/DQMLU, WEOB/DQMLL are mask signals. The data buses having 32 bits are divided into four groups of 8 bits, so that WE3B/DQMUU, WE2B/DQMUL, WE1B/DQMLU, WEOB/DQMLL are used to selectively mask the write/read operation.

Also, the digital signal device ASIC is basically connected with the address buses and the data buses, and has a signal line for transmitting the control signal as required. The digital signal device is for digital signal processing for special applications of the multi-chip module, and in collaboration with the microcomputer SH, takes charge of a dedicated specified signal processing. The signal transmission rate of these semiconductor chips is required to be high. In the case where the semiconductor chips are mounted by surface mounting on the wiring such as the buses formed on the mounting board, a signal transmission path of the shortest distance is formed to make possible high-speed signal exchange. Thus, a high performance is achieved.

In this embodiment, the microcomputer SH includes an interface corresponding to the flash memory FLASH. Specifically, the flash memory FLASH includes a data terminal I/O (7:0) and control signals WEB, SC, OEB, RDY/BusyB, and CEB. In keeping with this, the microcomputer SH also includes NA_IO (7:0) and control signals NA_WEB, NA_SC, NA_OEB, NA_RYBY and NA_CEB. The write/read operation between the microcomputer SH and the flash memory FLASH is slower than the operating speed with the SDRAM. Even in the case where the bonding wire makes up a signal transmission path, therefore, the transmission rate is not adversely affected. Thus, the MCM as a whole can be reduced in size while improving the performance thereof.

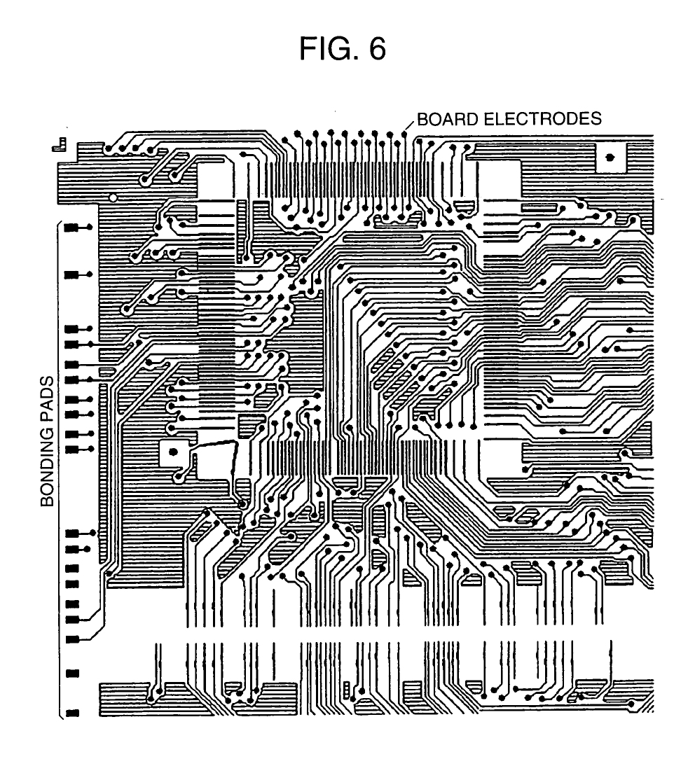

FIG. 6 is a diagram showing a wiring pattern of the mounting board of a multi-chip module according to an embodiment of the invention. The mounting board is configured of a multilayer wiring substrate of, say, eight layers. In FIG. 6, a part of the main surface of the mounting board where the semiconductor chips including the microcomputer SH and the memory SDRAM are mounted is illustratively shown.

In FIG. 6, straight lines and polygonal lines indicate wires, and black rectangles indicate bonding pads used for connecting the flash memory FLASH. The symbols * indicate board electrodes for surface mounting the semiconductor chips including the microcomputer SH and the memory SDRAM. In the upper part of FIG. 6, as shown in FIG. 2, board electrodes corresponding to the substantially square microcomputer SH are arranged, while board electrodes corresponding to the laterally long memory SDRAM are arranged in the lower part of FIG. 6. The bonding pads are arranged in vertical direction on the left side of FIG. 6.

The aforementioned configuration in which the flash memory FLASH is mounted back-to-back on the microcomputer SH and the memory SDRAM is not limited to a case in which the whole flash memory FLASH is mounted on the mounting surface of SH and SDRAM. In view of the fact that the bonding pads of the flash memory FLASH are aligned on one long side, the bonding pads of the mounting board can also be aligned as shown in FIG. 6. As a result, the area occupied by the bonding pads formed on the mounting board can also be reduced.

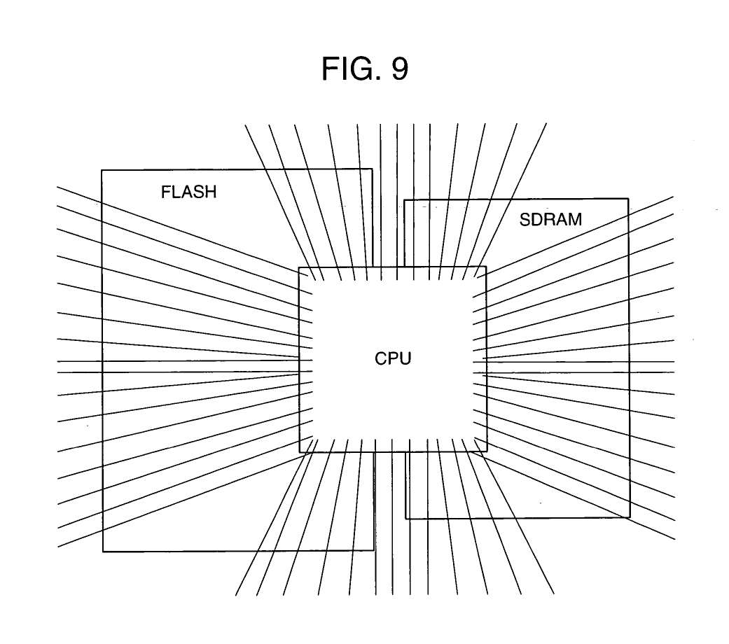

FIG. 9 is a schematic diagram showing the layout of a multi-chip module according to an embodiment studied before application of the invention. In this case, the microprocessor CPU is mounted back-to-back on the flash memory FLASH and the memory SDRAM. The microprocessor CPU has a multiplicity of external terminals along the periphery of the chip. Therefore, a multiplicity of bonding pads corresponding to the bonding pads of the CPU are required to be arranged distributively outside the flash memory FLASH and the memory SDRAM on the mounting board. Thus, the area occupied by the bonding pads on the mounting board is undesirably increased.

From the viewpoint of the performance of the circuit operation, on the other hand, the signal transmission path of the microprocessor CPU required to transmit the signal at high speed includes comparatively long bonding wires. This poses the problem that the transmission rate of the high-frequency clock and the signals synchronous with the clock is adversely affected by the comparatively large inductance component of the bonding wires. In the multi-chip module according to the invention, in contrast, the mounting board can be reduced in size on the one hand and the performance of the circuit operation is advantageously high on the other hand. However, Applicants do not intend to admit the example of FIG. 9 as prior art in the statute.

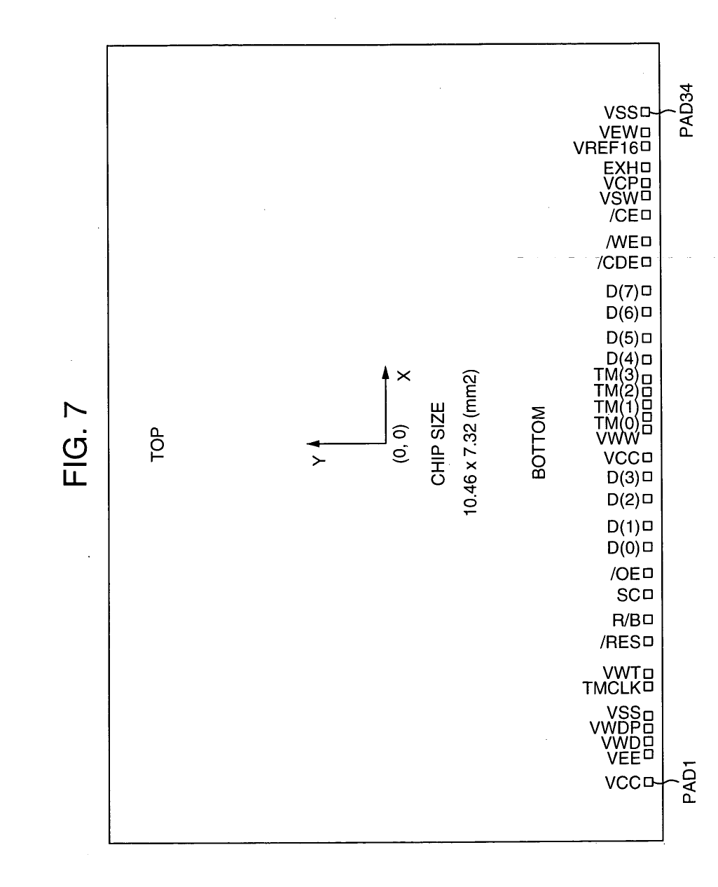

FIG. 7 shows a layout of the bonding pads of a flash memory according to an embodiment of the invention. The bonding pads PAD1 to PAD34 are arranged on one of the long sides (bottom) of the rectangular board. In addition to the signal pads shown in FIG. 5, the pads for the source voltages VCC, VSS and the operating voltage are also included.

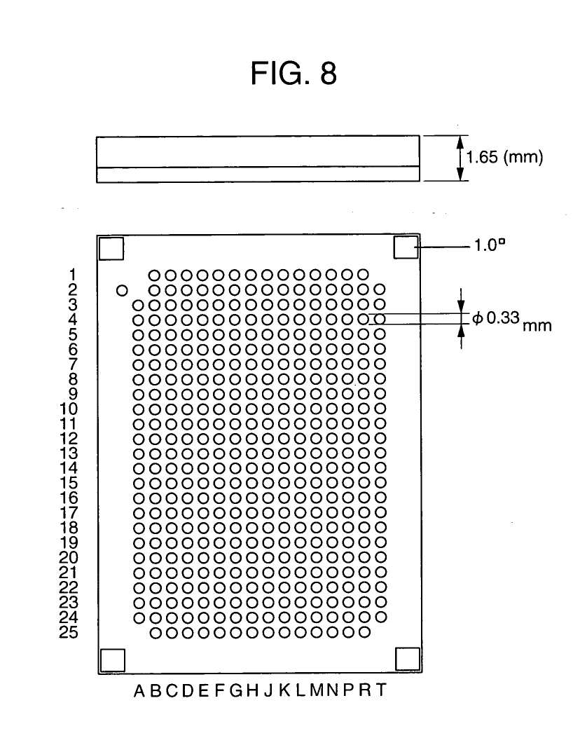

FIG. 8 is a diagram showing a general configuration of a multi-chip module according to an embodiment of the invention. The multi-chip module is as thin as 1.65 mm, and 1.70 mm (max), for example, and has solder balls constituting a total of 395 external terminals (pins) on the reverse side. The solder ball connectors (land) are each 0.33 mm in diameter φ and arranged at the pitch of 0.65 mm.

An explanation will be made below of an example of a multi-chip module of land grid array (LGA) type in which the semiconductor chips and the mounting board are coupled to each other by use of gold (Au)/solder (Sn or the like) without any ball-shaped protruded electrodes on the reverse side of the mounting board.

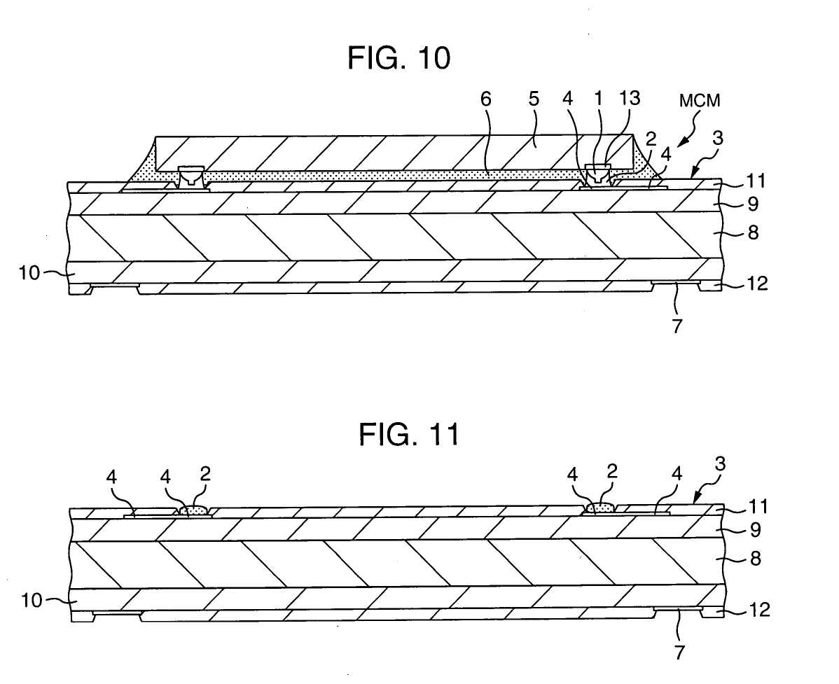

As shown in FIG. 10, the MCM according to this embodiment has a basically similar configuration to the MCM described with reference to FIGS. 1 to 8 above except for the difference described below. Specifically, the AU stud bumps 1 are each electrically and mechanically connected to the connector 4 of the mounting board 3 through a coupling member 2. Between the semiconductor chip 5 and the mounting board 3, an underfill resin 6 is filled to suppress the damage to the semiconductor chip 5 which otherwise might be caused by the concentration of thermal stress due to the difference in the coefficient of thermal expansion between the mounting board 3 and the semiconductor chip 5. Further, the reverse side of the mounting board 3 is formed with land electrodes 7 as external terminals for electrically connecting a printed wiring board (PCB), for example.

According to this embodiment, the ball-shaped protruded electrodes shown in FIGS. 1 to 8 are not formed, and therefore the module can be advantageously reduced in size and thickness. Though not shown, a barrier layer of Cr/Cu/Au or the like may be formed on the surface of the land electrodes 7. In this embodiment, a single semiconductor chip 5 is shown as a representative case, and each of SH, SDR and ASIC is mounted by flip chip connection on the mounting board 3.

The mounting board 3 is mainly configured of a rigid substrate (core substrate) 8, soft layers 9, 10 formed by the build-up method on the two opposite surfaces of the rigid substrate 8, and protective films 11, 12 formed in such a manner as to cover the soft layers 9, 10. The rigid substrate 8 and the soft layers 9, 10, though not shown in detail, have a multilayer wiring structure, for example. Each insulating layer of the rigid substrate 8 is formed of a high-elasticity resin substrate of glass fiber impregnated with polyimide resin or epoxy resin, while each insulating layer of the soft layers 9, 10 is formed of a low-elasticity epoxy resin, for example.

Each multilayer wiring configured of the rigid substrate 8 and the soft layers 9, 10 described above is formed of a metal film of copper (Cu), for example. The protective films 11, 12 are formed of polyimide resin, for example, for the primary purpose of protecting the wirings formed in the uppermost wiring layer of the soft layer 9, and intended to secure the adhesion of the adhesive resin with the semiconductor chip 5 at the time of packaging on the one hand and to control the expansion of wet solder at the packaging on the other hand. The protective film 12 is formed primarily to protect the wiring formed in the uppermost wiring layer of the soft layer 10, and controls the expansion of wet solder at the time of packaging of the land electrodes 7 with solder.

The semiconductor chip 5, though not limited, is configured mainly of a semiconductor substrate, a plurality of semiconductor devices formed on one main surface of the semiconductor substrate, multiple wiring layers including a plurality of insulating layers and wiring layers stacked in a plurality of stages on the one main surface of the semiconductor substrate, and a surface protective film (last protective film) formed in such a manner as to cover the multiple wiring layers. The semiconductor substrate is formed of, for example, single-crystal silicon, the insulating layer is formed of, for example, a silicon oxide film, and the wiring layer is formed of, for example, a metal film of aluminum (Al) or an aluminum alloy. The surface protective film is formed of an insulating film of, for example, silicon oxide or silicon nitride or an organic insulating film.

One main surface, which is in opposed relation with the other main surface (reverse side) of the semiconductor chip 5, is formed with a plurality of electrode pads 13. The plurality of the electrode pads 13 are formed on the uppermost wiring layer of the multiple wiring layers of the semiconductor chip 5, and exposed to a bonding opening formed in the surface protective film of the semiconductor chip 5. A plurality of the electrode pads 13 are aligned along each side of the semiconductor chip 5. A plurality of the electrode pads 13 each form a planar square of, say, 70 μm by 70 μm. Also, the plurality of the electrode pads are arranged at a pitch of about 85 μm.

The stud bumps 1 of gold (Au), for example, are arranged as protruded electrodes on one main surface of the semiconductor chip 5. A plurality of the stud bumps 1 are arranged on a plurality of electrode pads 13, respectively, arranged on the one main surface of the semiconductor chip 5, so that the stud bumps 1 and the electrode pads 13 are connected electrically and mechanically to each other. The stud bumps 1 of an Au wire are formed by the ball bonding method, for example, using thermal bonding and ultrasonic vibration at the same time. In the ball bonding method, a ball is formed at the forward end of each Au wire, after which the ball is thermally bonded to the electrode pad of the chip under the ultrasonic vibration, and then the Au wire is cut off from the ball portion thereby to form a bump. The stud bumps formed on the electrode pads, therefore, are firmly connected to the electrode pads.

The fabrication of the MCM described above will be explained with reference to FIGS. 11 to 13. FIGS. 11 to 13 are sectional views showing the essential parts for explaining the MCM fabrication. As shown in FIG. 11, a paste-like coupling material 2 is supplied by the dispensing method, for example, on each of the connectors 4 arranged in the chip mounting area on one main surface of the mounting board 3. A solder paste material is used as the coupling material 2. The solder paste material is made by mixing and kneading at least fine solder particles and the flux. This embodiment uses a solder paste material made by mixing and kneading solder particles composed of 98 wt % Pb (lead) and 2 wt % Sn (tin) having a melting point of about 300° C. The dispensing method is for coating the solder paste material by being ejected from a thin nozzle.

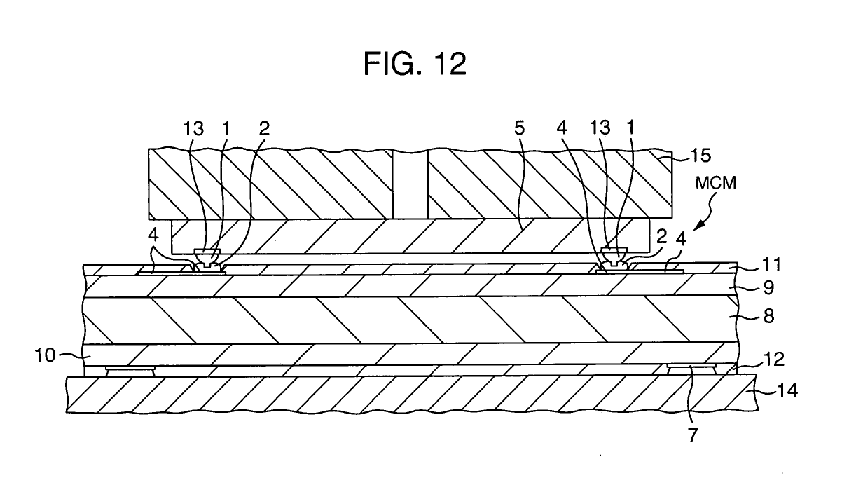

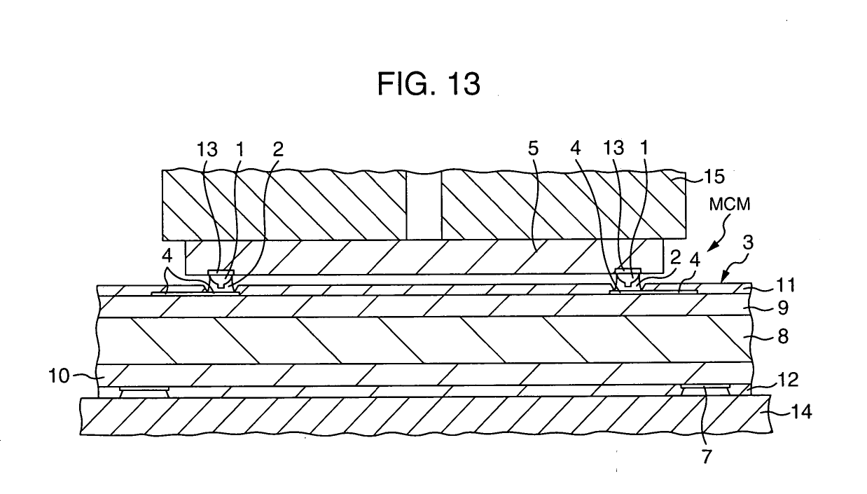

Next, as shown in FIG. 12, the mounting board 3 is arranged on a heat stage 14, after which the semiconductor chip 5 is conveyed by a collet 15 onto the chip mounting area in such a manner that the stud bumps 1 are set in position on the corresponding connectors 4. Then, the mounting board 3 is heated by the heat stage 14, while the semiconductor chip 5 is heated by the collet 15. In this way, as shown in FIG. 13, the coupling material 2 is melted, after which the melted coupling material 2 is aggregated. As a result, a semiconductor chip 5 is packaged in the chip mounting area on the one main surface of the mounting board 3.

As shown in FIG. 10, an underfill resin 6 is filled between the chip mounting area on the one main surface of the mounting board 3 and the semiconductor chip 5. After that, like the MCM shown in FIGS. 1 to 8, the flash memory FLASH is stacked back-to-back on the semiconductor chip 5. After that, the electrode pad of the flash memory FLASH is connected to the connector 4 of the mounting board 3 by wire bonding. In the last step, the four semiconductor chips SH, SDRAM, ASIC and FLASH and the bonding wire are encapsulated with resin thereby to complete the MCM substantially.

In mounting the MCM of LGA type on printed circuit board (PCB), a solder layer is formed by printing or the like on the connecting electrodes on PCB side, and the land electrodes formed on the reverse side of the MCM of LGA type are set in position with the connecting electrodes on PCB side. After that, the connecting electrodes are connected to each other by the solder layer through solder reflow. As an alternative, a thin solder layer may be formed in advance by printing or the like on the land electrodes of the MCM of LGA type.

Although FIGS. 1 and 2 show only four chips including SH, SDRAM, ASIC and FLASH, a chip for peripheral circuits may be additionally mounted. In such a case, the chip for the peripheral circuits is mounted face down on the mounting board by the protruded electrodes such as the Au stud bumps 1 in the same manner as SH, SDRAM or ASIC, so that the peripheral circuits are connected to the address buses and the data buses shared by the SH and ASIC shown in FIG. 5.

Specifically, the chips SH, SDRAM, ASIC and the peripheral circuits connected by bumps face down are connected to each other by common buses thereby to improve the operating speed of the module. The flash memory FLASH stacked on at least one chip, on the other hand, is connected to the electrode pads of the mounting board by the bonding wire, and connected to SH by a dedicated bus interface for independent connection with SH alone thereby to reduce the module size.

The invention achieved by the inventors is described above specifically with reference to the embodiments. However, this invention is not limited to the embodiments descried above, and variously modifiable without departing from the spirit and scope of the invention. For example, the multi-chip module may have mounted thereon a digital signal processor (DSP) or the like coprocessor operated in collaboration with the CPU in place of ASIC. In this case, the CPU and the digital signal processor are operated in a close relation by a control signal. By interconnecting the CPU and the digital signal processor through the board wiring by the imposition described above, therefore, a high performance can be realized. This invention finds wide applications for the semiconductor devices making up a multi-chip module.

The effects obtained by typical aspects of the invention disclosed herein are briefly explained below. A plurality of the first semiconductor chips for exchanging signals are surface-mounted on the surface of the mounting board, and a second semiconductor chip having most of the bonding pads thereof arranged along one side thereof is mounted in back-to-back relation with at least one of the first semiconductor chips, so that the bonding pads and the corresponding electrodes formed on the mounting board are connected to each other by wire bonding, and the first and second semiconductor chips and the bonding wire on the mounting board are encapsulated with a sealing material thereby to achieve a high performance and a small size of the multi-chip module.

What is claimed is:

1. A multi-chip module comprising:
a plurality of first semiconductor chips surface-mounted on a surface of a mounting board for exchanging signals with each other;
a second semiconductor chip mounted back-to-back with at least one of said plurality of first semiconductor chips, said second semiconductor chip having most of bonding pads thereof arranged along one side thereof;
bonding wires for connecting the bonding pads of said second semiconductor chip and corresponding electrodes formed on said mounting board; and
a sealing member for encapsulating said plurality of first semiconductor chips, said second semiconductor chip and the said bonding wire on said mounting board.

2. A multi-chip module according to claim 1,
wherein said plurality of first semiconductor chips include a microcomputer, a random access memory and a signal processing device for processing signals for specific applications, respectively and
wherein said second semiconductor chip is a nonvolatile memory.

3. A multi-chip module according to claim 2,
wherein said microcomputer and said random access memory or said signal processing device for processing the signal for specified applications which is connected to said microcomputer are interconnected by wiring formed on the mounting board by imposition; and
wherein said microcomputer includes an exclusive interface corresponding to said nonvolatile memory, said microcomputer and said nonvolatile memory being interconnected through said bonding wire.

4. A multi-chip module according to claim 3,
wherein said nonvolatile memory is mounted back-to-back with said first semiconductor chips including said microcomputer.

5. A multi-chip module according to claim 4,
wherein said first semiconductor chips mounted back-to-back with said nonvolatile memory include said microcomputer and said random access memory; and
wherein the long side of the semiconductor chip constituting said random access memory and the long side of the semiconductor chip constituting said nonvolatile memory are arranged orthogonally to each other.
